(19) United States
(12) Patent Application Publication
(10) Pub. No.: US 2011/0079767 A1
(43) Pub. Date: Apr. 7, 2011

(54) NITRIDE SEMICONDUCTOR DEVICE

(76) Inventors: Mathieu Xavier Senes, Oxford (GB); Katherine Louise Smith, Oxford (GB); Victoria Broadley, Oxford (GB); Stewart Edward Hooper, Oxford (GB)

(21) Appl. No.: 12/995,773

(22) PCT Filed: Jun. 3, 2009
(86) PCT No.: PCT/JP2009/060566

§ 371 Date: Dec. 2, 2010

(30) Foreign Application Priority Data
Jun. 4, 2008 (GB) 0810182.6

(51) Int. Cl. H01L 33/04; B82Y 20/00

(52) U.S. Cl. 257/13; 257/E33.008; 977/773; 977/950

(57) ABSTRACT

A nitride semiconductor device comprises: a layer structure including an active region (102) containing AlₓGa_{y}In_{1-x-y}N quantum dots layers (102a), and means (104a,104b) for applying an electric field across the active region to modify the spin orientation of excitons in the quantum dots. The exciton spin lifetime at 300K is, for at least a range of values of the electric field applied across the active region, at least 1 ns, more preferably at least 10 ns, and particularly preferably at least 15 ns or 20 ns. These lifetimes may be obtained by configuring the device such that the exciton binding energy is, for at least a range of values of the electric field applied across the active region, 25 meV or greater.

### TECHNICAL FIELD

The present invention relates to a nitride semiconductor device, in particular to a spin-optoelectronic or spintronic device and, in particular, to manipulating the exciton spin in nitride quantum dots using an electric field.

### BACKGROUND ART

There is currently considerable interest in the new emerging research area of spintronics and spin-optoelectronics which involves the study of active control and manipulation of spin degrees of freedom in semiconductor solid-state systems. Spintronics exploits the quantum spin states of electrons. The intrinsic spin of an electron may adopt one of two states, generally referred to as “spin-up” and “spin-down”, and, when an external field is applied, the energy level of a “spin-up” electron becomes different to the energy level of a “spin down” electron. Further background information may be found at Spintronics [Search conducted on May 13, 2008], the Internet <URL: https://en.wikipedia.org/wiki/Spintronics> Or in “Introduction to spintronics” by S. Bandyopadhyay and M. Cahay (Taylor and Francis, Boca Raton, 2007). Indeed, using the spin of particles instead of their charge has great potential for low power devices with integrated logic and storage functions. Though there has been a much extensive investigation of the spin properties in bulk and quantum well semiconductor structures in the last twenty years, efficient spin relaxation processes in these structures limit dramatically the spin lifetime of the carriers, which has prevented the demonstration of a working semiconductor-based spintronic device at room temperature. One promising solution to this problem is to use quantum dots, as they can provide strong confinement of the carriers. But even if quantum dot nanostructures have the advantage of strongly reducing the dramatic impact of carrier spin relaxation, quantum dots in the Gallium-based III-V and II-VI material systems have failed to show long spin lifetime and spin manipulation of carriers at room temperature.

For this purpose, there is a growing interest in the (Al,Ga,In)N material system, which is already broadly used in the fabrication of a large range of optoelectronic devices such as light emitting diodes, laser diodes, photovoltaic detectors or high power and high temperature electronic devices. Compared to the other III-V and II-VI material systems, the (Al,Ga,In)N material system is very promising for spintronic devices working at room temperature as it provides a large band gap, weak spin-orbit coupling and large exciton binding energy. The (Al,Ga,In)N system includes all materials with the formula AlₓGa_{y} In_{1-x-y}N, with 0≦x≦1, 0≦y≦1. Takeuchi et al. Appl. Phys. Lett. 88, 162114 (2006) measured the spin lifetime in cubic bulk GaN. They found spin lifetimes longer than 5 ns at very low temperature (below 100 K), but showed a dramatic decrease of the spin lifetime when the temperature was increased above 100 K. The fast spin relaxation at higher temperature can be explained by the strong spin relaxation processes present in bulk material, as mentioned before. However, spin lifetimes were found to be longer than in hexagonal GaN, as reported by T. Kuroda et al., Appl. Phys. Lett. 85, 3116 (2004), mainly because of the higher crystallographic symmetry for cubic materials.

Reducing the dimensionality of the system may lead to a cancellation of the effect of these efficient spin relaxation processes. But Julier et al., Phys. Statu Solidi (b) 216, 341 (1999) found short spin lifetimes in InGaN quantum wells even at low temperature. They proposed that the internal electric field naturally present in wurtzite nitride quantum wells may reduce the spin lifetime of the carriers. Moreover, raising the temperature unlocked fast spin relaxation processes leading to an even shorter spin relaxation time. So it seems that nitride quantum wells are not good candidates for long spin lifetimes.

Arakawa et al. Appl. Phys. Lett. 88, 083101 (2006) were the first to demonstrate that, using InGaN quantum dots, having relatively long spin lifetime (200 ps) with no temperature dependence could be possible. But despite the temperature independence, the spin lifetime in this system is still too short to be used in spintronic devices requiring long spin lifetime, possibly because the quantum dots used in this article were grown in the conventional wurtzite nitride material system, and a strong internal electric field was present in the quantum dots. As suggested by Julier et al., the internal electric field present in wurtzite nitride material system may reduce the spin lifetime of the carriers.

D. Lagarde et al. Phys. Rev. B 77, 041304 (2008) showed a quenching of the exciton spin lifetime in non polar cubic GaN quantum dots. Moreover, the exciton spin lifetime remains quenched even at room temperature because of the strong confinement and the large exciton binding energy provided by the quantum dots. However, there is still a lack of manipulation of the exciton spin, which is required in a practical spin-optoelectronic or spintronic device.

Pertinent prior art in terms of the basic theoretical considerations involved in the present invention is found in the book by G. Bastard, entitled “Wave mechanics applied to semiconductor heterostructures”, published by Les editions de physique, in 1992 and in the book by F. Meier and B. Zakharchenya, entitled “Optical Orientation”, Modern problems in condensed matter sciences, Amsterdam, in 1984.

### SUMMARY OF INVENTION

The present invention provides a nitride semiconductor device comprising: a layer structure including an active region containing AlₓGa_{y}In_{1-x-y}N quantum dots (0≦x<1 and 0≦y≦1), and means for applying an electric field across the active region to modify the spin orientation of excitons in the quantum dots.

The device is preferably configured so as to be operable at a temperature of greater than 100K, or at a temperature of greater than 150K. These are higher operation temperatures than can be attained by known spintronic devices based on semiconductor quantum dots.

The device is more preferably configured so as to be operable at room temperature for at least a range of values of the electric field applied across the active region (which range may or may not include zero electric field). The term “room temperature” as used herein is taken to mean a temperature of 300K (27° C.). In order for the device to be operable at 300K, the device is configured such that the exciton spin lifetime at 300K is, for at least a range of values of the electric field applied across the active region (which range may or may not include zero electric field), preferably at least 1 ns, is more preferably at least 10 ns, and particularly preferably is at least 15 ns or at least 20 ns. Configuring the device such that the exciton spin lifetime at 300K is at least ins (or at least 10 ns or at least 15 ns or at least 20 ns) ensures that effects in the device performance arising from exciton spin will be exhibited at 300K (and similarly, configuring the device such that the exciton spin lifetime at 100K (or 150K) is at least 1 ns (or at least 10 ns or at least 15 ns or at least 20 ns) ensures that effects in the device performance arising from exciton spin will be exhibited in device operation at 100K (or 150K)). Experimentally, it has been found that the present invention can provide exciton spin lifetimes longer than 20 ns at 300K.

The desired exciton spin lifetime will depend on the intended application, although, in general, a longer spin lifetime is always desirable. In quantum information processing, for example, the spin lifetime has to be longer than the time required to perform an operation on the spins. If the invention is applied to quantum computations, an exciton spin lifetime of 1 ns provides enough time to carry out several quantum operations (which are of the order of a picosecond timescale). If the invention is applied to a spin laser, as another example, it seems that spin lifetimes longer than 2.5 ns are required to demonstrate high degree of circular polarisation and low threshold current (Appl. Phys. Lett., Vol. 94, p 131108 (2009)). This document reported a 2.5 ns spin lifetime at 77K leading to a high degree of circular polarisation, but reported a low degree of polarisation at room temperature since the spin lifetime was much shorter at room temperature. When the present invention is applied to a spin laser it should enable a high degree of circular polarisation to be achieved at room temperature.

The device is preferably configured such that excitons in the quantum dots have a binding energy of 25 meV or greater for at least a range of applied electric fields across the active region. (The range of applied electric fields for which excitons in the quantum dots have a binding energy of 25 meV or greater may or may not include zero applied electric field.) It has been found that certain configurations of device (to be described below) have an exciton spin lifetime that is sufficiently large to allow room temperature operation, and this is believed to be due to the devices having excitons with an exciton binding energy of 25 meV or greater. Accordingly, by configuring the device such that the internal electric field, or built-in field, within the quantum dots is weak or zero the exciton binding energy can be made 25 meV or greater. This provides a long exciton spin lifetime at room temperatures (where a “long” exciton spin lifetime is preferably at least 1 ns, is more preferably at least 10 ns, and particularly preferably is at least 15 ns or at least 20 ns), and allows a spintronic device that is operable at room temperatures to be produced.

The device may be configured such that excitons in the quantum dots have a binding energy of 50 meV or greater for at least a range of applied electric field across the active region.

The dimensions of the quantum dots may be selected such that excitons in the quantum dots have a binding energy of 25 meV or greater for at least a range of applied electric field across the active region. They may be selected such that excitons in the quantum dots have a binding energy of 50 meV or greater for at least a range of applied electric field across the active region.

Quantum dots within the active regions may have each dimension less than 50 nm.

The layer structure may be disposed over a non-polar substrate. This also leads to a reduction in the built-in field and allows an exciton binding energy of 25 meV or greater to be obtained for at least a range of applied electric field across the active region.

The substrate may comprise one of cubic GaN, m-plane GaN and a-plane hexagonal GaN.

The means for applying the electric field may comprise electrodes disposed on opposite sides of active region.

The means for applying the electric field may comprise quantum wires.

The means for applying the electric field may be arranged to apply, in use, an electric field substantially perpendicular to the growth direction of quantum dots. Alternatively, they may be arranged to apply, in use, an electric field substantially parallel to the growth direction of quantum dots.

The means for applying the electric field may be arranged to apply, in use, an electric field having a component substantially opposite to the direction of the built in electric field of the quantum dots. In such a device the exciton spin lifetime is increased as the magnitude of the electric field applied site to the direction of the built in electric field of the quantum dots is increased.

The active layer may comprise two or more layers of quantum dots. Alternatively, it may comprise only a single layer of quantum dots.

The quantum dots may be elongate quantum dots.

The quantum dots may have interface anisotropy.

The device may be an optoelectronic device. It may be an optically pumped optoelectronic device.

Varying the electric field across the active region may change the intensity of light output from the device. Alternatively, varying the electric field across the active region may change the polarisation of light output from the device.

Though there have been many demonstrations of exciton spin manipulation in quantum dots in recent years, effort has continued to develop a semiconductor-based spintronic device working at room temperature. Even if quantum dot nanostructures have the advantage of strongly reducing the dramatic impact of carrier spin relaxation, Ga-based III-V and II-VI quantum dots have so far failed to show long spin lifetime and spin manipulation of carriers at room temperature.

In accordance with the principles of the present invention, a new class of devices is provided which offers the possibility of achieving room temperature spin manipulation of excitons in quantum dots grown in the (Al,Ga,In)N material system. Further, these devices provide long exciton spin coherence time at room temperature.

An exciton is, as will be known to a skilled person, a bound state of an electron and an imaginary particle called an “electron hole” or just a “hole” in an insulator or semiconductor. The hole is formed when an electron is excited into a higher energy band, for example following absorption of a photon. The missing electron in the band leaves a “hole” behind, which has opposite electric charge to the electron—so that the electron and hole are attracted together by the Coulomb force.

These advantages are realised by using nitride quantum dots exhibiting a weak effect of the internal electric field arising from both piezoelectric field and spontaneous polarisation field, or by using nitride quantum dots exhibiting little or no internal electric field, such that the exciton binding energy is 25 meV or greater—if the internal electric field is weak, or zero, the electron and hole of the exciton are not separated by the field to such an extent that the binding energy is reduced below 25 meV. This is achieved respectively by growing the quantum dots in such a way that their dimension, and particularly their height, provides an exciton binding energy larger than 25 meV (i.e. provides strong confinement), or by growing the quantum dots on non-polar substrates such as cubic GaN for example. (While the piezoelectric component of the internal electric field is present even if the quantum dots are grown on a non-polar substrate, this component is generally negligible and does not reduce the exciton binding energy below 25 meV. Furthermore, the effect of the piezoelectric field on the electron and hole of the exciton reduces as the size of the quantum dots reduces owing to the increased confinement, and the piezoelectric field has little or no effect on the electron and hole for quantum dots having typical dimensions of 50 nm or below.) It is also in the scope of this invention to provide a new way of controlling the exciton spin orientation with an electric field. As the exciton spin is robust up to room temperature because of the strong exciton binding energy in the (Al,Ga,In)N material system, the present invention uses an electric field to separate spatially the electron and the hole of the exciton via the quantum confined Stark effect. This leads to a reduction of the exciton binding energy. Thus, the spin relaxation processes occurring via the electron-hole exchange interaction produce the relaxation of the exciton spin. As a consequence, the exciton spin polarisation can change with the value of the electric field applied.

Alternatively, the applied electric field can be used to screen further the built-in electric field effect on the carriers in polar quantum dots. In this case, the exciton will show longer spin lifetime and higher spin polarisation degree under the applied electric field.

Thus it is an object of the present invention to produce a new class of spin-based semiconductor devices which provide long exciton spin lifetime at room temperature.

Another object is to provide a control of the exciton spin lifetime by an electric field.

The foregoing and other objectives, features, and advantages of the invention will be more readily understood upon consideration of the following detailed description of the invention, taken in conjunction with the accompanying drawings.

### BRIEF DESCRIPTION OF DRAWINGS

FIG. 1 is a schematic sectional view illustrating the makeup of a typical embodiment of a nitride quantum dot spin device of the present invention.

FIG. 2 is a schematic sectional view of the active region of a device in the AlGaInN material system as fabricated in the present invention.

FIG. 3 is a schematic sectional view of the active region of a device made with phase separated quantum dots in the AlGaInN material system in accordance with the present invention.

FIG. 4 is a schematic sectional view of a quantum dot spin device in the AlGaInN material system grown according to an embodiment of the present invention.

FIG. 5 shows the linear polarisation degree of the photoluminescence against wavelength at two different values of the applied electric field for a quantum dot spin device in the AlGaInN material system grown according to an embodiment of the present invention.

FIG. 6 is a schematic sectional view of a spin laser device in the AlGaInN material system using the present invention.

### REFERENCE SIGNS LIST

101 underlying layer(s) (substrate)
102 active region
102a quantum dot layer (quantum dots)
102b barrier layer
103 overlying layer(s)
104a back electrode (means for applying an electric field)
104b top electrode (means for applying an electric field)
105 voltage source (means for applying an electric field)
401 substrate
402 n-GaN layer
403 active region
404 p-GaN layer
405a top contact (means for applying an electric field)
405b bottom contact (means for applying an electric field)
406 bias potential (means for applying an electric field)
407 laser light
408 emitted light
601 substrate
602 buffer layer
603 first cladding layer
604 first optical guiding layer
605 active region
606 second optical guiding layer
607 second cladding layer
608 capping layer
609a top electrode (means for applying an electric field)
609b bottom electrode (means for applying an electric field)
610 bias potential (means for applying an electric field)
611 laser beam
612 emitted laser beam

### DESCRIPTION OF EMBODIMENTS

The ‘built-in electric field’ within a quantum dot refers to the electric field originating from both piezoelectric and pyroelectric fields. The built-in electric field which can reach several MV/cm in III-nitride quantum dots spatially separates the electron and hole to opposite ends of the quantum dot, as the electron and hole have opposite charges. The direction of the built-in electric field is generally along the growth direction of the quantum dot.

Hereafter, the present invention will be described in detail with reference to certain suitable forms of implementation thereof illustrated in the drawing figures.

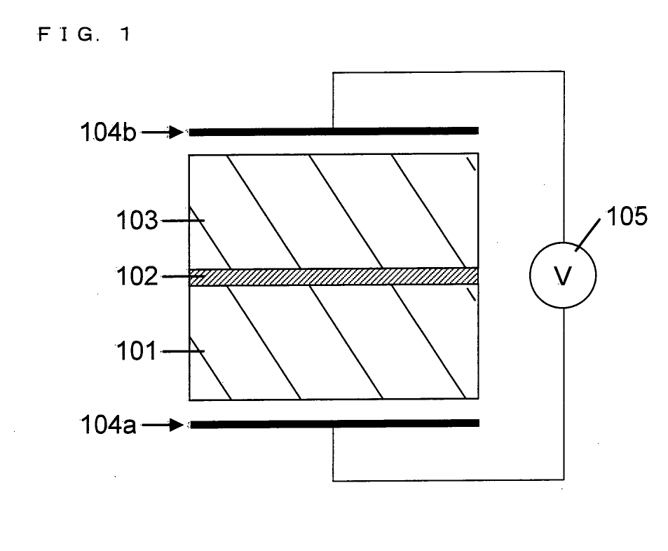

FIG. 1 is a sectional view illustrating the makeup of a typical embodiment of the nitride quantum dot spin device of the present invention.

In the figure there are shown the active region 102 of the device which contains nitride quantum dots, embedded in the structure of the device made of semiconductor materials. The device structure comprises one or more underlying layers depicted schematically as 101, the active region 102, and one or more overlying layers depicted schematically as 103 disposed over the active region. A back electrode 104a and a top electrode 104b are connected to a voltage source 105 in order to selectively apply an electric field across the active region 102.

Mention is next made of the description of the quantum dot active region 102 of the present invention.

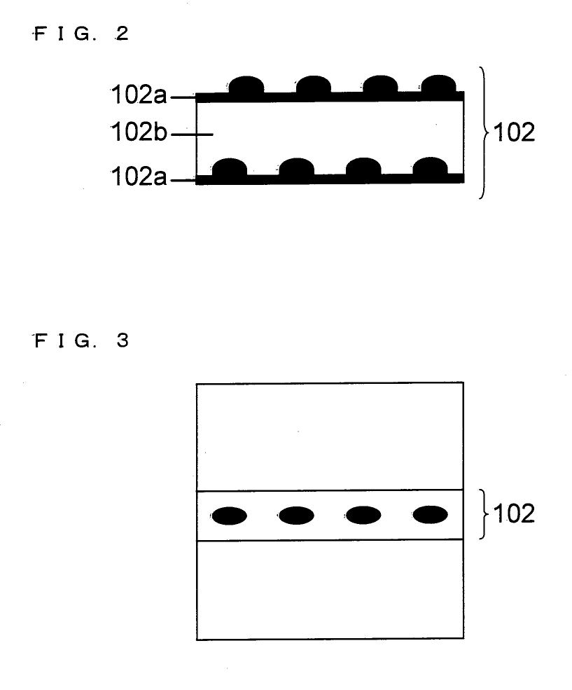

FIG. 2 is a schematic sectional view of a nitride active region of the present invention. The active region 102 of FIG. 2 may contain active layers of AlₓGa_{y}In_{1-x-y}N quantum dots 102a disposed on the underlying layers 101 (see FIG. 1) of the (Al,Ga,In)N structure or the barrier layers 102b separating different quantum dot layers 102a. The AlₓGa_{y}In_{1-x-y}N quantum dots may have a composition wherein 0≦x≦1 and 0≦y≦1, therefore including GaN, InN, InGaN, AlGaN and AlInGaN. The quantum dots may have a size wherein all three dimensions are each less than 50 nm. The quantum dots are preferably not intentionally doped.

The nitride quantum dots in the quantum dot layers 102a of the active region 102 of the present invention are preferably such that the exciton spin within the dots is not affected, or is only weakly affected, by the built-in electric field of the quantum dots so that the exciton spin lifetime at 300K is, for at least a range of values of the electric field applied across the active region by the electrodes 104a,104b (which range may or may not include zero electric field), preferably at least 1 ns, is more preferably at least 10 ns, and particularly preferably is at least 15 ns or at least 20 ns. Configuring the device such that the exciton spin lifetime at 300K is at least 1 ns (or at least 10 ns or at least 15 ns or at least 20 ns) ensures that effects in the device performance arising from exciton spin will be exhibited at 300K. Alternatively, for certain applications an operating temperature of 100K or above may be acceptable, in which case the nitride quantum dots of the quantum dot layers 102a are configured so that the exciton spin lifetime at the desired operating temperature is, for at least a range of values of the electric field applied across the active region by the electrodes 104a,104b, more preferably at least 10 ns, and particularly preferably is at least 15 ns or at least 20 ns.

As explained above, the desired exciton spin lifetime may be obtained if the exciton binding energy is 25 meV or greater, preferably 50 meV or greater, for at least a range of applied electric fields across the active region. One way to achieve this is for a device of the present invention to be grown on a non polar substrate, so that the pyroelectric and piezoelectric field components of the built-in field are negligible and have no significant effect on the exciton spin lifetime, so that the exciton binding energy is 25 meV or greater. The non polar substrate may be cubic GaN, m-plane or a-plane hexagonal GaN or any equivalent non polar substrate in the (Al,Ga,In)N material system.

Alternatively, a polar substrate in the (Al,Ga,In)N material system may be used in the present invention. In this case, the quantum dots may have a size wherein their height leads to a strong confinement of the exciton, such that the built-in electric field does not reduce strongly the electron and hole wavefunctions overlap of the exciton via the quantum confined Stark effect, so that the exciton binding energy is 25 meV or greater. Therefore, the quantum dots may have a size wherein their height provides a confinement to the exciton such that the exciton binding energy is more than 25 meV, and preferably more than 50 meV, for at least a range of applied electric fields across the active region.

The active region 102 may contain one or more quantum dot layers 102a. The quantum dot layers 102a may vary in composition. The quantum dot layers 102a may vary in thickness.

The quantum dot active layers 102a may contain one or more quantum dots. The quantum dot density of the quantum dot active layers 102a may be sufficient to provide a lateral electronic coupling between the excitons present in adjacent quantum dots, or may not be sufficient to provide any lateral electronic coupling. Having electronically coupled quantum dots (as a result of coupling between the excitons present in adjacent quantum dots) may be useful where the invention is applied to, for example, a quantum computer or quantum logic gates.

The active region 102 of the present invention of FIG. 2 may contain one or more (Al,Ga,In)N barrier layers 102b. The bandgap of the barrier layers 102b may be larger than the bandgap of the quantum dot layers 102a. The barrier layers 102b may have a thickness of greater than 1 nm and less than 50 nm. If the thickness of a barrier layer is below 1 nm, the layer would be unlikely to function effectively as a barrier layer. At thicknesses below 1 nm it is probable that the barrier layer would not entirely cover the underlying quantum dot layer so that the next quantum dot layer to be grown would be grown on the underlying quantum dot layer so that quantum dots would not be formed—and if quantum dots were formed it is likely that they would be of low quality. Also, it has been found that performance of an LED with an active region that includes several quantum dot layers decreases significantly if the barrier layers have a thickness greater than 50 nm. barrier. This is believed to be due to a decrease in the material quality of the active region and to the increased overall electrical resistance of the active region (which increases as the thickness of the barrier layers increases).

The barrier layers 102b may all be identical. The barrier layers 102b may vary in composition. The barrier layers 102b may vary in thickness. The barrier layers 102b may be not intentionally doped, or alternatively may be doped n-type or p-type. For example, doping the barrier layers 102b may change the value of the piezoelectric field in the case of quantum dots grown over a polar substrate, and so modify the electric field value required to screen the piezoelectric field and obtain a long exciton spin lifetime.

The active region 102 of FIG. 2 of the present invention may contain two or more quantum dot layers 102a such that the quantum dots are vertically aligned (ie, such that the quantum dots in one layer are vertically above those in the lower layer). The vertically aligned quantum dots of the quantum dot layers 102a may provide vertical electronic coupling to the excitons present in the quantum dots in different layers, or may not provide vertical electronic coupling.

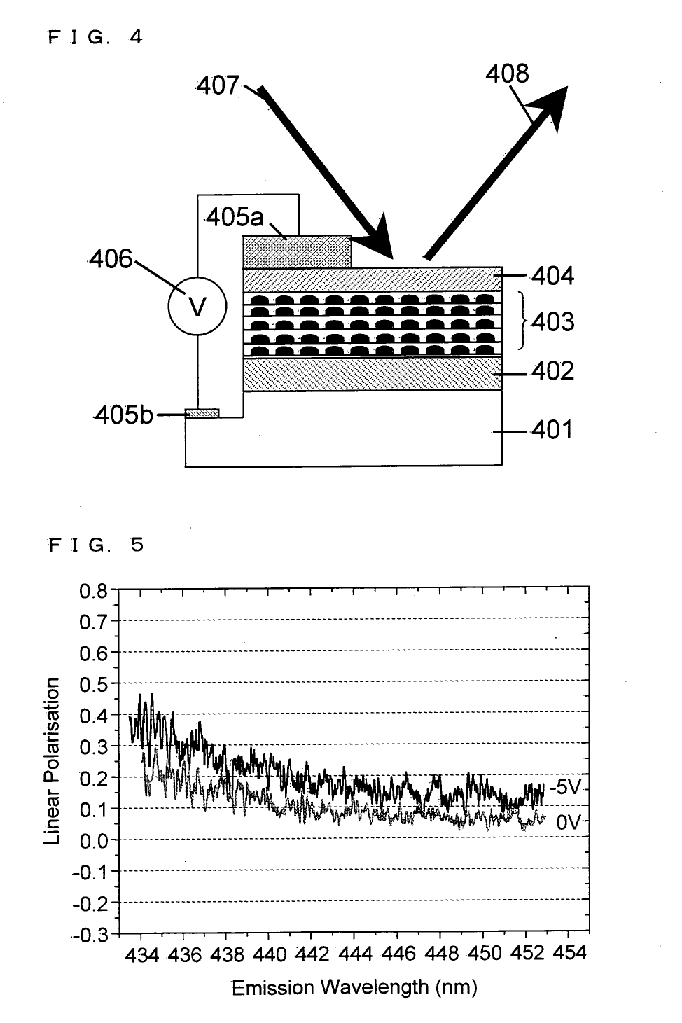

The nitride quantum dots of the quantum dot layers 102a of the active region 102 may have a structure elongated in the direction normal to their growth axis and/or may have an interface anisotropy. In this case, the exciton eigenstates may be linearly polarised states, so the operation of the present invention will be based on linearly polarised excitonic states. A very slight elongation of a quantum dot is enough to break its symmetry and thus obtain linearly polarised states: for example from 4% elongation is enough. (In the example of FIG. 2 or FIG. 4, the growth direction of the quantum dots is perpendicular to the substrate 401; in order to obtain elongation the size of the quantum dot in one lateral direction (ie a direction parallel to the substrate) is made different to the size of the quantum dot in an orthogonal lateral direction. Where interface anisotropy is present, again, if the degree of anisotropy is sufficiently large that the symmetry of the quantum dot is broken (and the required degree of anisotropy will depend on the shape and the composition of the quantum dot), the states are linearly polarised. This can happen if there is a reduction of the symmetry at the interface between the quantum dot and the surrounding material (ie the orientation of the chemical bonds at the interfaces are not all in the same direction).

Alternatively, the nitride quantum dots of the quantum dot layers 102a of the active region 102 may not have a structure elongated in any direction normal to their growth axis and may not have an interface anisotropy. In this case, the exciton eigenstates may be circularly polarised states, so the operation of the present invention will be based on circularly polarised excitonic states. Whether circularly or linearly polarised eigenstates are preferred depends on which kind of device the invention is applied to. For example, in a light-emitting device, the polarisation of the eigenstates will be at the origin of the polarisation of the emitted light (so that circularly polarised exciton eigenstates will lead to circularly polarised light). In the case of a quantum computer, as another example, linear eigenstates may be preferred (as a quantum computer requires superposition of states and linear spin states are linear superposition of circularly polarised states).

The quantum dots of the quantum dot layers 102a of FIG. 2 may be grown by Stransky-Krastanov growth process. Alternatively they may be grown by one skilled in the art by any suitable nitride quantum dot growth process. This includes but is not limited to Volmer-Weber growth process, or phase-separated quantum dots as shown in FIG. 3.

The active region 102 of the present invention may be grown using molecular beam epitaxy as a growth method, or could be grown by one skilled in the art using any growth method for the growth of (Al,Ga,In)N material-based quantum dots. This includes but is not limited to metal-organic chemical vapour deposition, or hybrid vapour phase epitaxy.

Mention is next made of an operation of the present spin-based device.

Spin-polarised excitons optically or electrically generated in the quantum dots of the quantum dot layers 102a of the active region 102 of the present device will keep their spin orientation during all the exciton lifetime because of the absence of, or the weak effect of, the built-in electric field and the strong exciton binding energy. This means that neither the electron spin nor the hole spin relax during all the exciton lifetime. For example, in an optoelectronic device made according to this present invention which emits light, the emitted light will be polarised. The spin polarisation of the exciton can be monitored by the polarisation degree of the emitted light. As a consequence of the spin orientation quenching of the excitons, the polarisation degree of the emitted light will remain constant during all the exciton lifetime.

In the embodiment of FIG. 1, a voltage is selectively applied between the electrodes 104a and 104b such that the electric field generated between electrodes 104a and 104b is strong enough to modify the spin orientation of the excitons in the quantum dots of the quantum dot layers 102a. As a consequence, the spin relaxation time of the excitons is reduced. For example, the polarisation degree of the emitted light will be reduced in the case of a light emitting optoelectronic device made according to the present invention. The electric field generated by the voltage applied to the electrodes 104a and 104b may reduce the exciton binding energy by modifying the band structure of the quantum dots via the quantum confined Stark effect and thus separating the electron and the hole. The exciton spin relaxation is controlled by the value of the voltage applied to the electrodes 104a and 104b.

Electrodes 104a and 104b are typically made from a metal. An electrical potential difference is maintained between electrode 104a and 104b. For example, the electrical potential can be any applicable value.

The electrical potential applied to the electrodes 104a and 104b may be modulated, or may not be modulated (i.e. continuous).

In the embodiment of FIG. 1, the electrodes 104a and 104b are positioned generally perpendicular to the growth direction of the quantum dots, such that the direction of the electric field generated by the electrodes 104a,104b is parallel, or substantially parallel, to the growth direction of the quantum dots, i.e. the electric field is vertical with the device orientation shown in FIG. 1. (In FIG. 1 it is assumed that the growth direction is substantially perpendicular to the plane of the substrate). Alternatively, the electrodes 104a,104b may be arranged such that the direction of the electric field generated by the electrodes 104a,104b is perpendicular or substantially perpendicular to the growth direction of the quantum dots, i.e. the electric field is horizontal with the device orientation shown in FIG. 1, or the electrodes 104a,104b may be oriented to provide an electric field at any angle to the growth direction of the quantum dots.

As noted, in FIG. 1 it is assumed that the growth direction is substantially perpendicular to the plane of the substrate. The invention is not in principle limited to the growth direction being substantially perpendicular to the plane of the substrate (although this is currently the most common case), and the electrode arrangement shown in FIG. 1 may be modified to allow for the growth direction not being substantially perpendicular to the plane of the substrate.

Alternatively, in the case of polar nitride quantum dots, the electric field generated by the electrodes 104a and 104b may be used to reduce the built-in electric field effect on the excitons, and hence an increase of the exciton spin polarisation rate and an increase of the exciton spin lifetime will occur. This requires that the electrodes 104a,104b apply an electric field which has a non-zero component opposite to the built-in field (which includes the possibility that the electric field applied by the electrodes 104a,104b is substantially opposite to the built-in field). This embodiment may be used to obtain a device which, when no electric field is applied across the active region 102 by the electrodes 104a,104b, has a low exciton spin lifetime and in which the exciton spin lifetime increases as the electric field applied across the active region 102 is increased. Thus, such a device will therefore have an exciton binding energy of below 25 meV when no electric field is applied across the active region 102 by the electrodes 104a,104b but will have an exciton binding energy of 25 meV or above for applied electric fields that are large enough to sufficiently reduce the effect of the built-in electric field on the excitons. Thus, in such a device the exciton spin lifetime will increase as the electric field across the active region increases.

Mention is next made of a specific example of the present invention.

A device of the present invention having a structure as shown in FIG. 4 is fabricated using polar In_{0.15}Ga_{0.75}N/GaN quantum dots in an active region 403. The device structure is a light emitting diode structure grown by molecular beam epitaxy. The InGaN quantum dot active region 403 is embedded between an n-doped GaN layer 402 and a top p-doped GaN layer 404. The device is grown over a substrate 401. A top contact 405a may be of gold. The bottom contact 405b may be of indium. The active region 403 of the device comprises, in this embodiment, 5 layers 102a of In_{0.15}Ga_{0.75}N quantum dots separated by a non-intentionally doped GaN barrier layer 102b having a thickness of 6 nm. The quantum dots have dimensions such that their height is around 2 nm and their lateral size at the bases is around 10 nm. Such dimensions lead to a strong confinement of the excitons, and a weak built-in electric field effect is observed (exciton radiative lifetime around 400 ps—see M. Senes et al., Phys. Rev. B 75, 045314, 2007). The quantum dots are elongated in the direction normal to their growth axis and/or may have interface anisotropy such that the exciton eigenstates are linearly polarised states. The spin polarised excitons are generated optically by a linearly polarised laser light 407 focused on the portion of the p-type GaN layer 404 that is not covered by the top contact 405a. The light 408 emitted by the device is collected and analysed in polarisation. First, the linear polarisation of the emitted light 408 is measured after a linearly polarised laser excitation, with no voltage applied between the contacts 405a, 405b. Then, a fixed reverse bias potential 406 of −5V is applied to the contacts 405a and 405b, and the polarisation of the emitted light 408 is measured. The reverse bias potential 406 applied to the LED is used to avoid electrical injection of non-polarised carriers in the quantum dots.

FIG. 5 shows a graph of observational results illustrating the change of the exciton polarisation with the bias potential applied between top contact 405a and bottom contact 405b. The linear polarisation degree of the emission is shown to double from 10% to 20% when the bias potential is increased from 0V to −5V.

The results of FIG. 5 demonstrate that an applied electric field screens the built-in electric field present in the polar InGaN quantum dots of the device of the present invention. The screening of the built-in electric field leads to an increase of the exciton binding energy, and thus to a stronger suppression of the effects of the spin relaxation processes. As a consequence, the polarisation degree of the photoluminescence is increased.

Mention is next made of a further specific example of the present invention.

According to another embodiment of the present invention, the electric-field-induced spin switching of the excitons may be used to construct an optical-pumped spin laser working at room temperature.

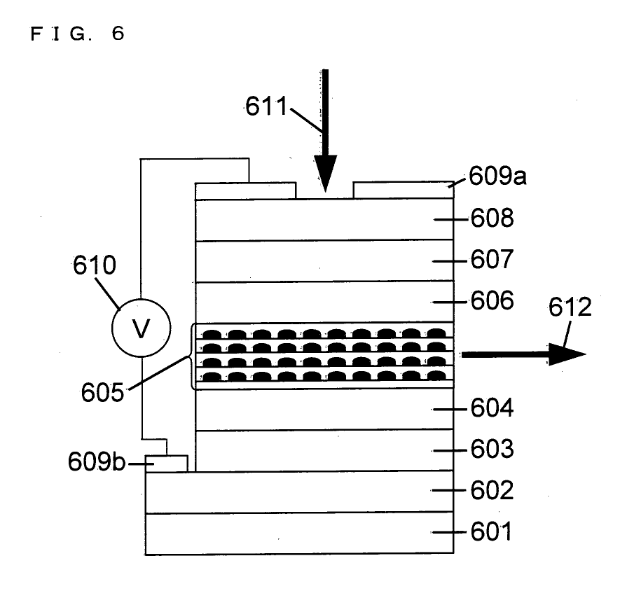

FIG. 6 is a schematic diagram of an optical pumped spin laser using the present invention. The spin laser of FIG. 6 may contain a buffer layer 602 made in the (Al,In,Ga)N material system disposed on the substrate 601. A first cladding layer 603, in this example an (Al,Ga)N cladding layer 603, is disposed on the buffer layer 602. A first optical guiding layer 604, in this example an (Al,Ga,In)N optical guiding layer 604, is disposed on the first cladding layer 603. A second optical guiding layer 606, in this example an (Al,Ga,In)N optical guiding layer 606, is disposed over the active region 605, which contains nitride quantum dots as described in the first embodiment. A second cladding layer 607, in this example an (Al,Ga)N cladding layer 607, is disposed on the second optical guiding layer 606. Finally, a capping layer 608 is disposed on the second cladding layer 607. Electrodes 609a and 609b are disposed on top and bottom, respectively, of the spin laser structure, and an electrical bias potential 610 is applied between the electrodes 609a and 609b to introduce an electric field through the quantum dot active region 605.

A polarised excitation laser beam 611 used as a pump beam is focused on the top of the spin laser structure, through an aperture made in the top electrode 609a. The emitted laser beam 612 of the spin laser is emitted perpendicular to the growth axis of the device of the present invention.

The polarised excitation laser beam 611 creates spin polarised excitons in the nitride quantum dots of the active region 605 of the spin laser structure of FIG. 6. As a consequence, the emitted laser beam 612 of the spin laser is polarised. Moreover, the gain of the laser depends on the spin polarisation of the excitons. If the excitons are spin polarised, the gain curve of the spin laser is above threshold and the spin laser is switched on. When a bias potential 610 is applied between the electrodes 609a and 609b such that the exciton spin loses its orientation, the gain curve of the spin laser is below threshold and the spin laser switches off. Thus, varying the bias potential applied between the top electrode 609a and the bottom electrode 609b (and hence varying the electric field applied across the active region 102) can turn the device between its OFF state and its ON state and thus change the intensity of light output from the device.

Furthermore, when the device is in its ON state, the applied bias potential 610 may be used to modulate the intensity of light output from the spin laser by modulating the spin orientation of the excitons in the nitride quantum dots of the active region. This will change the spin polarisation of the excitons; this changes the gain of the laser and hence changes the laser output.

Pertinent prior art in terms of the basic operation principles of a spin laser involved in the present example of a device using the invention is found in the article by M. Oestreich et al., entitled “spin injection, spin transport and spin coherence”, Semicond. Sci. Technol. 17, 285-297 (2002) and in German patent No. DE 10243944 issued on Apr. 1, 2004, to M. Oestreich.

The advantages of the present spin laser are that the spin laser can operate at constant carrier density, avoiding temperature fluctuations and shifts in wavelength. Moreover, both spin orientation and carrier density can be modulated and the spin laser may carry twice the information compared to a conventional laser with the same modulation frequency. The main advantage of using the present invention is that the spin laser can work at room temperature.

It should be understood that the use of electrodes 405a,405b; 609a,609b in FIGS. 4 and 6 is one suitable way to generate an electric field across the quantum dots in the present invention, but the invention is not limited to this and any suitable method of applying an electric field across the quantum dots may be used.

For example, but not be limited to, the nitride quantum dots of the active region may be embedded in one or more quantum wires, in contact with one or more quantum wires or almost in contact with one or more quantum wires. In these embodiments, the quantum wires may be used to generate an electric field across the quantum dots.

Further, the present is not limited in its application to the examples shown. In particular, although the invention has been described with reference to optoelectronics devices the invention is not so limited and may be applied to electronic devices in general, through electrical injection of spin-polarised carriers and electrical detection of the spin polarisation. It may be used in a large number of different types of devices, for example in quantum logic gates, quantum computation, quantum information, spin memories, spin transistors, spin light emitting diodes, and all other devices which may require and be based on the manipulation of exciton spin at room temperature using nitride quantum dots as described in preferred embodiment. Where the invention is applied to devices other than optoelectronic devices, the device will have an active region that is generally similar in structure to the active regions described in this application. The devices will also be required to have suitable means for selectively applying an electric field across the active region, for example according to any of the ways described herein. The remaining parts of the device structure will contain layers suitable to define a suitable structure for the particular type of device (so, for example, to define a transistor structure when the invention is applied to an spin transistor).

The invention is not limited to an active region in which the quantum dots have a height of around 2 nm and a lateral size of around 10 nm, and the height and lateral dimensions of the quantum dots may take any value up to 50 nm. In general, however, the height of the quantum dots will be less than their lateral dimensions.

Although the present invention has hereinbefore been set forth with respect to certain illustrative embodiments thereof, it will readily be appreciated to be obvious to those skilled of the art that many alterations thereof, omissions therefrom and additions thereto can be made without departing from the essences of scope of the present invention. Accordingly, it should be understood that the invention is not intended to be limited to the specific embodiments thereof set forth above, but to include all possible embodiments that can be made within the scope with respect to the features specifically set forth in the appended claims and to encompass all the equivalents thereof.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

1. A nitride semiconductor device comprising: a layer structure including an active region containing AlₓGa_{y}In_{1-x-y}N quantum dots, where 0≦x≦1 and 0≦y≦1, and means for applying an electric field across the active region to modify the spin orientation of excitons in the quantum dots.

2. A nitride semiconductor device as claimed in claim 1 and configured so as to be operable at a temperature of greater than 100K.

3. A nitride semiconductor device as claimed in claim 1 and configured so as to be operable at room temperature.

4. A nitride semiconductor device as claimed in claim 1 and configured such that excitons in the quantum dots have a binding energy of 25 meV or greater for at least a range of applied electric field across the active region.

5. A nitride semiconductor device as claimed in claim 1 and configured such that excitons in the quantum dots have a binding energy of 50 meV or greater for at least a range of applied electric field across the active region.

6. A nitride semiconductor device as claimed in claim 4 wherein the dimensions of the quantum dots are selected such that excitons in the quantum dots have a binding energy of 25 meV or greater for at least a range of applied electric field across the active region.

7. A nitride semiconductor device as claimed in claim 5 wherein the dimensions of the quantum dots are selected such that excitons in the quantum dots have a binding energy of 50 meV or greater for at least a range of applied electric field across the active region.

8. A nitride semiconductor device as claimed in claim 1 wherein quantum dots within the active region have each dimension less than 50 nm.

9. A nitride semiconductor device as claimed in claim 1 wherein the layer structure is disposed over a non-polar substrate.

10. A nitride semiconductor device as claimed in claim 9 wherein the substrate comprises one of cubic GaN, m-plane GaN and a-plane hexagonal GaN.

11. A nitride semiconductor device as claimed in claim 1 wherein the means for applying the electric field comprises electrodes disposed on opposite sides of the active region.

12. A nitride semiconductor device as claimed in claim 1 wherein the means for applying the electric field comprises quantum wires.

13. A nitride semiconductor device as claimed in claim 1 wherein the means for applying the electric field are arranged to apply, in use, an electric field substantially perpendicular to the growth direction of quantum dots.

14. A nitride semiconductor device as claimed in claim 1 wherein the means for applying the electric field are arranged to apply, in use, an electric field substantially parallel to the growth direction of quantum dots.

15. A nitride semiconductor device as claimed in claim 1 wherein the means for applying the electric field are arranged to apply, in use, an electric field having a component substantially opposite to the direction of the built in electric field of the quantum dots.

16. A nitride semiconductor device as claimed in claim 1 wherein the active region comprises two or more layers of quantum dots.

17. A nitride semiconductor device as claimed in claim 1 wherein the quantum dots are elongate quantum dots.

18. A nitride semiconductor device as claimed in claim 1 wherein the quantum dots have interface anisotropy.

19. A nitride semiconductor device as claimed in claim 1 and comprising an optoelectronic device.

20. A nitride semiconductor device as claimed in claim 19 and comprising an optically pumped optoelectronic device.

21. A nitride semiconductor device as claimed in claim 19 wherein varying the electric field across the active region changes the intensity of light output from the device.

22. A nitride semiconductor device as claimed in claim 19 wherein varying the electric field across the active region changes the polarisation of light output from the device.
